(19) United States
(12) Patent Application Publication
(10) Pub. No.: US 2015/0155441 A1
(43) Pub. Date: Jun. 4, 2015

(54) LED package and method for producing the same

(71) Applicants: Andrei Alexeev, St. Petersburg (RU); Sergey Popper, St. Petersburg (RU)

(72) Inventors: Andrei Alexeev, St. Petersburg (RU); Sergey Popper, St. Petersburg (RU)

(21) Appl. No.: 14/407,812

(22) PCT Filed: Jun. 15, 2012
(86) PCT No.: PCT/EP2012/061442

§ 371 Date: Dec. 29, 2014

(51) Int. Cl. H01L 33/40; H01L 33/62; H01L 27/15; H01L 33/00

(52) U.S. Cl. CPC H01L 33/40; H01L 33/005; H01L 33/62; H01L 27/15; H01L 2933/0033; H01L 2933/0066

(57) ABSTRACT

LED (“light emitting diode”) package (1) comprising a substrate (2) with a top side (9) and a bottom side (10), and at least one LED die (4), the substrate (2) having circuitry (3) arranged on its bottom side (10), the at least one LED die (4) comprising a bottom surface (6) exhibiting at least two separated contact areas (7, 8) for electrical connection. In order to realise an LED package (1) with mechanically robust electrical connections that can be simultaneously produced, according to the present invention, it is provided that the at least one LED die (4) is at least partially arranged in the substrate (2), and that at least one of the at least two contact areas (7, 8) is electrically connected to the circuitry (3) by a contact electrode (11) consisting of a film of conductive material (22).

### FIELD OF THE INVENTION

The present invention relates to an LED (“light emitting diode”) package comprising a substrate with a top side and a bottom side, and at least one LED die, the substrate having circuitry arranged on its bottom side for supplying the at least one LED die with power, the at least one LED die comprising a light-emitting top surface and a bottom surface exhibiting at least two separated contact areas for electrical connection, and the bottom surface facing in the same direction as the substrate bottom side.

Furthermore, the present invention relates to a method for producing an LED (“light emitting diode”) package comprising at least one LED die with a light-emitting top surface and a bottom surface exhibiting at least two separated contact areas for electrical connection.

### STATE OF THE ART

LED (“light emitting diode”) packages form a basis for producing LED based light sources and comprise at least one LED die (or chip) and a substrate, to which the LED die is fixed and which usually is transparent and heat conducting. Furthermore optical elements, like lenses, may be part of an LED package.

The substrate usually comprises circuitry for enabling the supply of the LED dies with electrical power. Accordingly, the LED dies have to be electrically connected to the circuitry. The usual way to provide for this electrical connection is to use wire bonding, i.e. wires, usually made of aluminium, copper, or gold, are welded with one end to a contact area (anode or cathode) of the LED die and with the other end to the circuitry. In case of light emitting diodes for indication purposes the whole structure is then encapsulated in an epoxy compound, which may include additional luminescent materials for converting the colour of the light emitted by the LED die.

The point where the bond wire is welded to an LED electrode is the mechanically weakest element in such constructions. Furthermore, the welding procedure is performed on each chip individually with the aid of complicated and expensive equipment. This is time consuming and cost intensive.

It is the object of the present invention to overcome these limitations. Particularly, it is the object of the present invention to provide an LED package with mechanically robust electrical connections between LED dies and the circuitry. Furthermore, it is the object of the present invention to provide an LED package with electrical connections between LED dies and the circuitry that are produced simultaneously in a batch process, thereby saving time and costs. Finally, it is also an object of the present invention to improve the efficiency of the LED package by accounting for optimised heat dissipation.

### SUMMARY OF THE INVENTION

According to the present invention mechanically robust electrical connections between LED (“light emitting diode”) dies and circuitry of an LED package are realised by contact electrodes consisting of a film of conductive material. These contact electrodes allow for a batch process production, i.e. essentially all electrical connections between at least two separated contact areas on a bottom surface of each LED die and circuitry situated on a bottom side of a substrate can be produced simultaneously.

As a precondition for this kind of contact electrode production the LED dies have to be arranged in the substrate instead of on the substrate. This in turn allows for the LED bottom surfaces to be aligned with the substrate bottom side—ideally the LED bottom surfaces are planar and flush with the substrate bottom side, which is planar too, preferably—and more or less planar contact electrodes can be produced. In dependence how well the LED bottom surfaces and the substrate bottom side are aligned the contact electrodes deviate from a perfectly planar shape and exhibit a certain shape in a direction perpendicular to the substrate bottom side. The latter is the case, particularly, if the LED dies are only partially arranged in the substrate and protrude with their bottom surfaces over the substrate bottom side a little bit.

Each LED die emits light from a top surface. Depending how the LED dies are arranged in the substrate, the emitted light might have to travel through part of the substrate and exit the substrate at a substrate top side. In this latter case the substrate must not be opaque. Apart from that condition, circuitry may also be arranged on the substrate top side, of course.

Therefore, an LED (“light emitting diode”) package is provided, comprising a substrate with a top side and a bottom side, and at least one LED die, the substrate having circuitry arranged on its bottom side for supplying the at least one LED die with power, the at least one LED die comprising a light-emitting top surface and a bottom surface exhibiting at least two separated contact areas for electrical connection, and the bottom surface facing in the same direction as the substrate bottom side, and according to the present invention, the at least one LED die is at least partially arranged in the substrate, and in that at least one of the at least two contact areas is electrically connected to the circuitry by a contact electrode consisting of a film of conductive material

The LED package may be produced in a highly economic way if the at least one LED die comprises exactly two contact areas, one being an anode and the other being a cathode, and each contact area of the at least one LED die being connected to the circuitry by a contact electrode consisting of a film of conductive material. In a preferred embodiment each and every LED die of the LED package comprises exactly two contact areas—one being an anode and the other being a cathode—that are connected to the circuitry by contact electrodes, each consisting of a film of conductive material.

Analogously, a method for producing an LED (“light emitting diode”) package is provided, comprising at least one LED die with a light-emitting top surface and a bottom surface exhibiting at least two separated contact areas for electrical connection, and according to the present invention, the method comprises the following steps
arranging of the at least one LED die in a substrate, with the bottom surface facing in the same direction as a substrate bottom side;
depositing a film of conductive material, thereby forming contact electrodes for electrically connecting the at least two contact areas to circuitry on the substrate bottom side.

In this way all contact electrodes are formed simultaneously. A planar LED bottom surface aligned to flush with a planar substrate bottom side, i.e. the LED bottom surface being coplanar with the substrate bottom side, is advantageous for this batch process.

Note that the contact electrodes may constitute part of or even the whole circuitry on the substrate bottom side. This means that also circuitry may be formed simultaneously with the contact electrodes.

Usually, even if the LED dies comprise more than two contact areas each, the method comprises the connection of only two contact areas per LED die. Correspondingly, in a preferred embodiment of the method according to the present invention, it is provided that the contact electrodes are simultaneously formed for two contact areas of each LED die.

Each film forming one contact electrode is continuous, i.e. electrically conducting. Furthermore, each film may consist of several layers. In a preferred embodiment of the LED package according to the present invention, it is provided that the film of conductive material forming the respective contact electrode consists of a single layer or of multiple layers of metal, like chromium, copper, aluminium, or nickel. In principle, the sequence of layers with different metals can be arbitrarily chosen.

However, the film of conductive material does not have to be a metallic layer or multilayer. Instead, in another preferred embodiment of the LED package according to the present invention, it is provided that the film of conductive material forming the respective contact electrode consists of a solidified conductive paste, preferably of a dried conductive ink or a dried solution of conductive polymers.

As written above it is advantageous for the production of planar contact electrodes if the LED bottom surfaces are coplanar with the substrate bottom side. In practice, a tilt between the LED bottom surfaces and the substrate bottom side of not more than 5 degrees is tolerable. Furthermore, an alignment tolerance of 50 μm, preferably 10 μm is acceptable, with this alignment tolerance being measured between the substrate bottom side and the LED bottom surface along a direction perpendicular to the substrate bottom side. Correspondingly, in a preferred embodiment of the LED package according to the present invention, it is provided that the bottom surface of the at least one LED die is coplanar with the substrate bottom side, with an alignment tolerance of 50 μm, preferably 10 μm.

The LED dies can be arranged in the substrate in different ways. For example, LED dies may be arranged in both recesses and holes of the substrate. Thereby, a “recess” constitutes a dead-end hole of the substrate, a “hole” a through-hole of the substrate. Therefore, in a preferred embodiment of the LED package according to the present invention, it is provided that the at least one LED die is arranged in a respective recess of the substrate, comprising an inner surface, or in a respective hole of the substrate, comprising an inner surface. The inner surface of the respective substrate recess is delimited by the substrate bottom side, the inner surface of the respective substrate hole by both the substrate bottom side and the substrate top side.

In order to improve heat conduction and dissipation, respectively, in a preferred embodiment of the LED package according to the present invention, it is provided that a section of the inner surface of a respective hole of the substrate is coated with metal, for example copper. Essentially the whole inner surface of the respective substrate hole may be coated with metal, except a small rim where the inner surface attaches to the substrate bottom side, in order to prevent electrical short circuits. Improving heat dissipation fosters the efficiency of the LED package. Furthermore, also the substrate top side may be metal coated, in order to further improve heat conduction and dissipation, respectively, as well as LED package efficiency.

In order to fix each LED die in its respective substrate recess or hole a compound is used which fills a volume between each LED die and the inner surface of the respective substrate recess or hole. Therefore, in a preferred embodiment of the LED package according to the present invention, it is provided that the at least one LED die is fixed in the respective recess or in the respective hole by a compound, which is positioned between the at least one LED die and the inner surface, the compound being a polymer compound like an acrylate, a siloxane, or an epoxy. Of course, the compound may also be a mixture of several materials. For example, the compound, e.g. siloxane, may contain luminescent material (phosphors), in order to convert the colour of the light emitted by the LED die. At least in this case the compound has to be transparent, i.e. the compound must not be opaque.

In case that the LED die is arranged in a respective substrate hole, the (transparent) compound can further be used as optical element. Particularly, a convex or concave lens may be formed by the compound through which the light emitted from the LED top surface has to travel. Therefore, in a preferred embodiment of the LED package according to the present invention, it is provided that the compound has a boundary surface facing into the same direction as the top surface of the LED die and being delimited by the inner surface of the respective hole, with the boundary surface having a convex or a concave shape with respect to the top surface.

In principle, the substrate can be made of a wide range of materials, particularly of materials known for the production of printed circuit boards (PCBs), e.g. glass epoxy with or without a copper core, ceramics, woven fiberglass cloth with an epoxy resin binder that is flame-resistant, or solidified compound. Usage of PCBs as substrates provides for a highly economic production of LED packages. Therefore, in a preferred embodiment of the LED package according to the present invention, it is provided that the substrate is made of the same material as a known printed circuit board, for example of aluminium or glass-reinforced epoxy laminate sheets.

As stated above the substrate may be made of compound. In this case the LED die may be embedded in the substrate. Therefore, in a preferred embodiment of the LED package according to the present invention, it is provided that the at least one LED die is embedded in the substrate, with the substrate being made of a compound, the compound being a polymer compound like an acrylate, a siloxane, or an epoxy. Of course, the compound may also be a mixture of several materials, as detailed above.

In order to realise LED dies embedded in the substrate, in a preferred embodiment of the method according to the present invention, it is provided that the arrangement of the at least one LED die in the substrate comprises the following steps:
fixing of the at least one LED die on a flat auxiliary support, with the bottom surface facing the auxiliary support;
enclosing the at least one LED die by compound, wherein the compound is confined within an auxiliary frame fixed on the auxiliary support;
solidifying of the compound, thereby forming the substrate with at least one embedded LED die. After that the substrate with the at least one embedded LED die is removed from the auxiliary support.

When enclosing the LED dies with compound it is important to avoid formation of air bubbles. In order to remove air bubbles vacuum degasification may be applied.

Depending on the compound, solidification can be triggered in different ways, e.g. by application of heat or by exposure to UV light.

As mentioned above the method for producing an LED package according to the present invention involves the deposition of a film of conductive material, thereby forming the contact electrodes. In turn, the contact electrodes may always constitute part of or even the whole circuitry. Depositing the film of conductive material can be done in different ways. In a preferred embodiment of the method according to the present invention, it is provided that the deposition of the film of conductive material comprises the following steps:
aligning a mask with the at least two contact areas, the mask having openings corresponding to the shapes of the contact electrodes to be formed;
evaporating a single layer or multiple layers of metal, like chromium, copper, aluminium, or nickel, through the mask openings.

In this way the contact electrodes for all LED dies (preferably two contact electrodes per LED die) can be formed simultaneously. The mask openings correspond to the planar or two-dimensional shape of the contact electrodes and resemble a direct image of the contact electrodes to be formed. The thickness of the contact electrodes, measured along a direction perpendicular to the substrate bottom side, is determined by the amount of material deposited.

In principle, the sequence of layers with different metals can be arbitrarily chosen, including a periodical and an alternating order.

The evaporation of the metal layer/s is preferably done using at least one thermal evaporator and/or at least one magnetron sputtering source and/or at least one electric arc evaporator, with the evaporation being carried out in a vacuum chamber. The latter typically implies high vacuum conditions with typical pressures of about 10̂-6 mbar or below.

Similarly, the deposition of a film of conductive material can be done by first evaporating metal layer/s and consecutively applying photolithography for forming the contact electrodes. Correspondingly, in a preferred embodiment of the method according to the present invention, it is provided that the deposition of the film of conductive material comprises the following steps:
evaporating a single layer or multiple layers of metal, like chromium, copper, aluminium, or nickel, onto the whole bottom surface of the at least one LED die and the substrate bottom side;
coating of the metal layer/s with photoresist;
aligning a mask with the at least two contact areas, the mask having openings corresponding to the shapes of the contact electrodes to be formed;
exposing of the photoresist through the mask openings;
removing the mask;
developing of the photoresist;
etching of sections of the metal layer/s not covered by photoresist.

Also in this way the contact electrodes for all LED dies (preferably two contact electrodes per LED die) can be formed simultaneously. The mask openings correspond to the planar or two-dimensional shape of the contact electrodes, with the exact embodiment of the mask openings depending on whether a positive or negative photoresist is used.

In case of a positive photoresist, its exposed regions are soluble by a developer and therefore washed off in the developing process. Hence, the positive photoresist remains and protects the underlying metal layer/s from consecutive etching in its unexposed regions. Accordingly, in case of positive photoresist “having openings corresponding to the shapes of the contact electrodes to be formed” means that the mask openings resemble a negative image of the contact electrodes to be formed.

In case of a negative photoresist, its unexposed regions are soluble by a developer and therefore washed off in the developing process. Hence, the negative photoresist remains and protects the underlying metal layer/s from consecutive etching in its exposed regions. Accordingly, in case of negative photoresist “having openings corresponding to the shapes of the contact electrodes to be formed” means that the mask openings resemble a direct image of the contact electrodes to be formed.

The thickness of the contact electrodes, measured along a direction perpendicular to the substrate bottom side, is again determined by the amount of material deposited.

Also, the sequence of layers with different metals can principally be arbitrarily chosen, including a periodical and an alternating order.

The evaporation of the metal layer/s is preferably done using at least one thermal evaporator and/or at least one magnetron sputtering source and/or at least one electric arc evaporator, with the evaporation being carried out in a vacuum chamber. The latter typically implies high vacuum conditions with typical pressures of about 10̂-6 mbar or below.

In order to provide for contact electrodes that are essentially coplanar with respect to each other, a dielectric layer is applied for planarization. In this dielectric layer, which, for example, is made of a poly(p-xylylene) polymer, also known under the trade name Parylene, openings are formed. These openings preferably resemble a direct image of the planar shape of the contact electrodes to be formed and are correspondingly aligned with the contact areas. Metal is evaporated through these openings and onto the dielectric layer, thereby forming a continuous film of metal in the dielectric layer openings, the dielectric layer, and in-between. In a last step the metal is removed from the dielectric layer in regions not belonging to the contact electrodes and/or the circuitry and coplanar contact electrodes and/or circuitry remain. This last step may be done by photolithography, for example. Note that in principle it is also possible to form one big opening per LED, covering and aligned with both the cathode and anode of the respective LED die. After evaporation of the metal, the metal has to be removed not only from the dielectric layer in regions not belonging to the contact electrodes and/or circuitry, but also from the region between the cathode and anode (the contact areas), in order to avoid short circuits. Hence, in another preferred embodiment of the method according to the present invention, it is provided that the deposition of the film of conductive material comprises the following steps:
coating of the whole bottom surface of the at least one LED die and the substrate bottom side with an electrically isolating, planar dielectric layer, preferably made of a poly(p-xylylene) polymer or a polyimide;
forming of at least one opening in the dielectric layer—preferably by plasma etching, laser ablation, or photolithography—, with the at least one opening being aligned with the at least two contact areas;
evaporating a single layer or multiple layers of metal, like chromium, copper, aluminium, or nickel, onto the dielectric layer and through the at least one opening of the dielectric layer;
removing the metal layer/s from regions not belonging to the contact electrodes and/or circuitry, preferably by photolithography.

Also in this way the contact electrodes for all LED dies (preferably two contact electrodes per LED die) can be formed simultaneously.

Furthermore, the sequence of layers with different metals can principally be arbitrarily chosen, including a periodical and an alternating order.

In order to avoid the usage of vacuum chambers, in another preferred embodiment of the method according to the present invention, it is provided that the deposition of the film of conductive material comprises the following steps:
aligning a mask with the at least two contact areas, the mask having openings corresponding to the shapes of the contact electrodes to be formed;
applying of a conductive paste through the mask openings, preferably by using a spreading knife;
removing the mask;
solidifying of the conductive paste.

Also in this way the contact electrodes for all LED dies (preferably two contact electrodes per LED die) can be formed simultaneously. The mask openings correspond to the planar or two-dimensional shape of the contact electrodes and resemble a direct image of the contact electrodes to be formed. The thickness of the contact electrodes, measured along a direction perpendicular to the substrate bottom side, is determined by the amount of material deposited.

Depending on the conductive paste composition, solidification can be done in different ways and typically involves polymerisation of the paste, e.g. in case the conductive paste is a polymer solution filled with small conductive particles like silver powder.

In case a photosensitive conductive paste is used, further steps similar to photolithography are involved. Thus, in another preferred embodiment of the method according to the present invention, it is provided that the deposition of the film of conductive material comprises the following steps:
applying of a photosensitive conductive paste onto the whole bottom surface of the at least one LED die and the substrate bottom side;
aligning a mask with the at least two contact areas, the mask having openings corresponding to the shapes of the contact electrodes to be formed;
exposing of the photosensitive conductive paste through the mask openings;
removing the mask;
removing not-solidified photosensitive conductive paste.

Also in this way the contact electrodes for all LED dies (preferably two contact electrodes per LED die) can be formed simultaneously. The mask openings correspond to the planar or two-dimensional shape of the contact electrodes. Analogously to photolithography, there exist conductive pastes that behave either similar to negative photoresists or similar to positive photoresists. This means that depending on the specific type of the conductive paste exposure to UV light can trigger or impede solidification of the conductive paste. Accordingly, the mask openings have to resemble either a direct or a negative image of the contact electrodes to be formed.

The photosensitive paste which is not solidified is removed using a proper solvent, e.g. an alkali solution such as a sodium carbonate (Na₂CO₃) solution.

The thickness of the contact electrodes, measured along a direction perpendicular to the substrate bottom side, is determined by the amount of material deposited.

### BRIEF DESCRIPTION OF FIGURES

The invention will be explained in closer detail by reference to preferred embodiments, with

FIG. 1 showing a cross-sectional view of an LED package according to the invention, with an LED die being arranged in a recess of a substrate

FIG. 2 showing a cross-sectional view of an LED package according to the invention, with an LED die being arranged in a hole of a substrate

FIG. 3 showing a cross-sectional view of an LED package according to the invention, with an LED die being embedded in a substrate

FIG. 4 showing a top view of an LED die with contact areas connected to essentially planar contact electrodes

FIG. 5 showing a three-dimensional view of an LED die with contact areas connected to essentially planar contact electrodes

FIG. 6 showing a top view of a mask used in the production of essentially planar contact electrodes

FIG. 7 showing a top view of an LED package with nine LED dies contacted with essentially planar contact electrodes produced using the mask shown in FIG. 6

FIG. 8 showing a cross-sectional view of an LED package during a step in a photolithographic production process of essentially planar contact electrodes

FIG. 9 showing a cross-sectional view of an LED package with photolithographically produced essentially planar contact electrodes

FIG. 10 showing a cross-sectional view of a substrate comprising a hole with a metal-coated inner surface

FIG. 11 showing a cross-sectional view of an LED package during a step in a production process of essentially planar contact electrodes, with conductive paste being applied through a mask

FIG. 12 showing a cross-sectional view of an LED package during a step in a production process of a substrate with an embedded LED die

FIG. 13 showing a cross-sectional view of a low-power dissipation LED for indication purposes according to the prior art, with bond wiring as electrical connection between LED electrodes and circuitry

FIG. 14 showing a cross-sectional view of an LED package with a dielectric layer covering the LED bottom surface and the substrate bottom side

FIG. 15 showing a cross-sectional view of an LED package during a step in a production process of essentially planar contact electrodes, with a photosensitive conductive paste being exposed to UV light through a mask

### WAYS FOR CARRYING OUT THE INVENTION

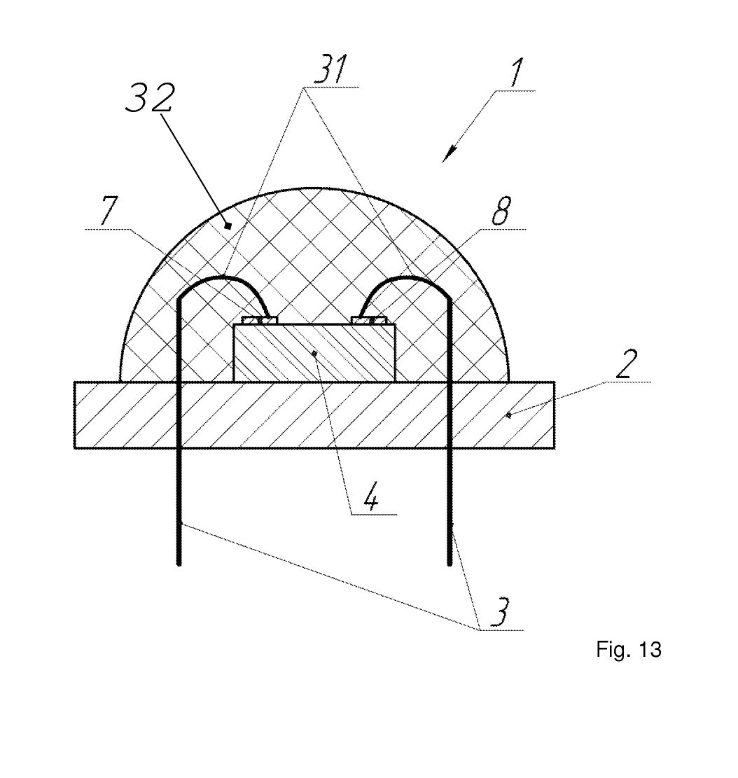

FIG. 13 shows a cross-sectional view of a low-power dissipation LED (“light emitting diode”) package 1 for indication purposes according to the prior art. The LED package 1 comprises an LED die 4 with an anode 7 and a cathode 8 that are connected to circuitry by means of wire bonding 31. The LED die 4 is arranged on a substrate 2 and—together with the wire bonding 31 and part of the circuitry 3—encapsulated in an epoxy case 32. Connecting the wire bonding 31 to the anode 7 and cathode 8 is a process which can hardly be done batch-wise and which is therefore economically unfavourable. Furthermore, the wire bonding 31 constitutes a mechanical weakness.

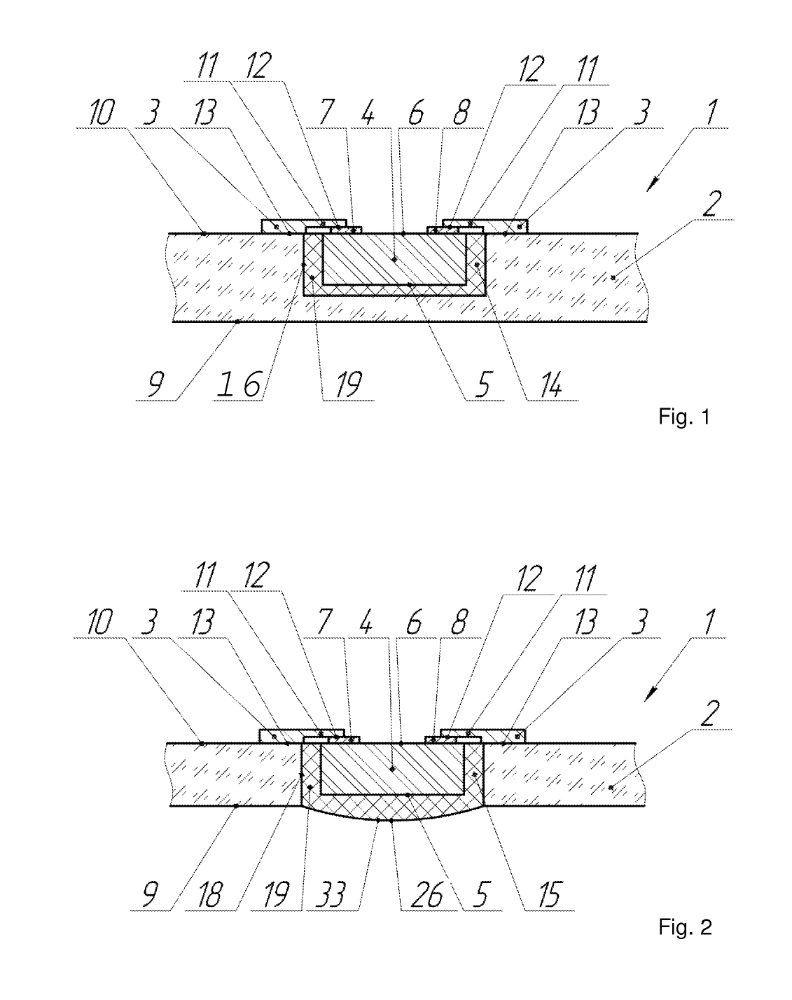

In order to overcome these limitations, the present invention provides for an LED package 1 of which FIG. 1 shows a preferred embodiment in cross-sectional view. An LED die 4 is arranged in a substrate 2, more precisely in a recess 14 of the substrate 2, wherein the recess 14 is a dead-end hole in a planar bottom side 10 of the substrate 2. Recesses 14 can be produced using laser ablation or plasma etching, for example. Furthermore, circuitry 3, for supplying the LED die 4 with power, is arranged on the bottom side 10, thereby covering sections 13 of the substrate bottom side 10.

The LED die 4 comprises a planar bottom surface 6, which is aligned with the bottom side 10 of the substrate 2 in such a way that the LED bottom surface 6 and the substrate bottom side 10 are coplanar. Thereby, tolerances in angular and translational displacement between the LED bottom surface 6 and the substrate bottom side 10 are acceptable—typically not more than 5 degrees and not more than 50 μm, preferably not more than 10 μm. On its bottom surface 6 the LED die 4 comprises an anode 7 and a cathode 8 as separated contact areas for electrical connection.

The LED die 4 further comprises a planar top surface 5, from which light is emitted if the LED die 4 is properly supplied with electrical energy. The LED die 4 is arranged in the respective recess 14 such that its top surface 5 faces into the same direction as a substrate top side 9.

The LED die 4 is fixed in the respective recess 14 by means of a compound 19, which fills a volume between an inner surface 16 of the respective recess 14 and the LED die 4. The inner surface 16 is delimited by the substrate bottom side 10 only.

Since the light emitted from the LED top surface 5 has to travel through the compound 19 and part of the substrate 2 (the light exits at the substrate top side 9), both the compound 19 and the substrate 2 have to be transparent for the light—at least to a certain extent. The compound 19 is made of a polymer compound, like an acrylate, a siloxane, or an epoxy, and additionally may contain luminescent material (phosphors) for converting the light colour.

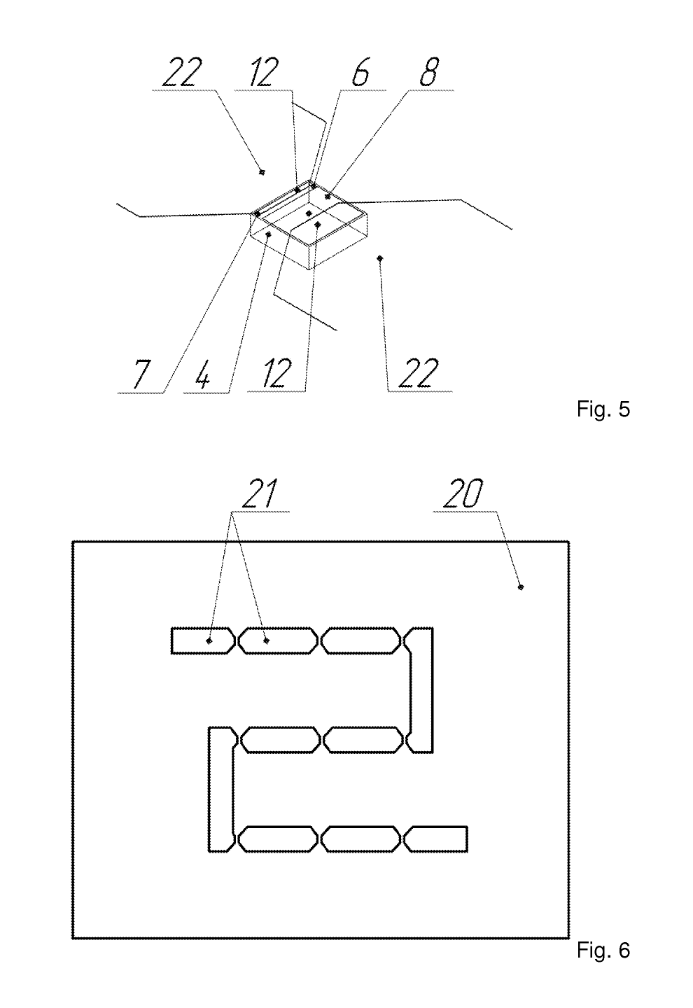

The anode 7 and cathode 8 are connected to the circuitry 3 by contact electrodes 11 made of a film of conductive material 22 (cf. FIG. 4), which covers sections 12 of the contact areas and the anode 7/cathode 8, respectively. Thus, the contact electrodes 11 are essentially planar. For better illustration, FIG. 4 shows a top view and FIG. 5 shows a three-dimensional view of an LED die 4 with anode 7 and cathode 8 connected to essentially planar contact electrodes 11. Note that the film of conductive material 22 forming the contact electrodes 11 may also form part of or even the whole circuitry 3.

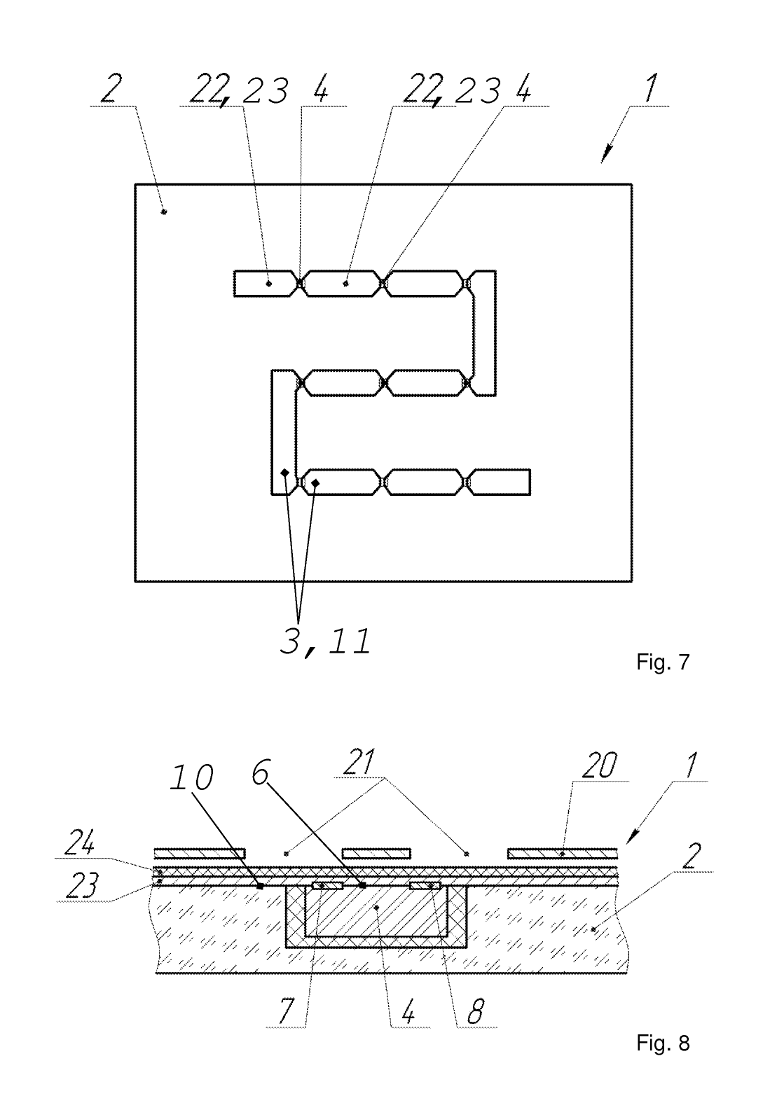

Note that in FIG. 1 only a cut-out with one LED die 4 is shown, but of course many LED dies 4 can—and usually will—be arranged in the substrate 2, cf. FIG. 7.

In an alternative embodiment the LED die 4 is arranged in a respective hole 15 of the substrate 2, with the hole 15 being a through-hole through the substrate 2. Holes 15 can be produced using laser cutting or etching, for example. FIG. 2 shows a cut-out of such embodiment. The LED die 4 is fixed in the hole 15 by the compound 19, which fills a volume between an inner surface 18 of the respective hole 15 and the LED die 4. The inner surface 18 is delimited by both the substrate bottom side 10 and the substrate top side 9.

In the case the LED die 4 is arranged in a respective hole 15 of the substrate 2, the substrate 2 may be opaque. Particularly in this case, the substrate 2 can be made of a material used in the production of printed circuit boards (PCBs), preferably aluminium or glass-reinforced epoxy laminate sheets, in order to save costs.

In order to improve heat conduction and dissipation, respectively, a metal coating 28 can be applied to a section 36 of the inner surface 18. The section 36 comprises essentially the whole inner surface 18 of the respective substrate hole 15, except a small rim where the inner surface 18 attaches to the substrate bottom side 10, in order to prevent electrical short circuits, see FIG. 10. Improving heat dissipation fosters the efficiency of the LED package 1. Furthermore, also sections 17 on the substrate top side 9 may be metal coated, as shown in FIG. 10, in order to further improve heat conduction and dissipation, respectively, as well as LED package efficiency.

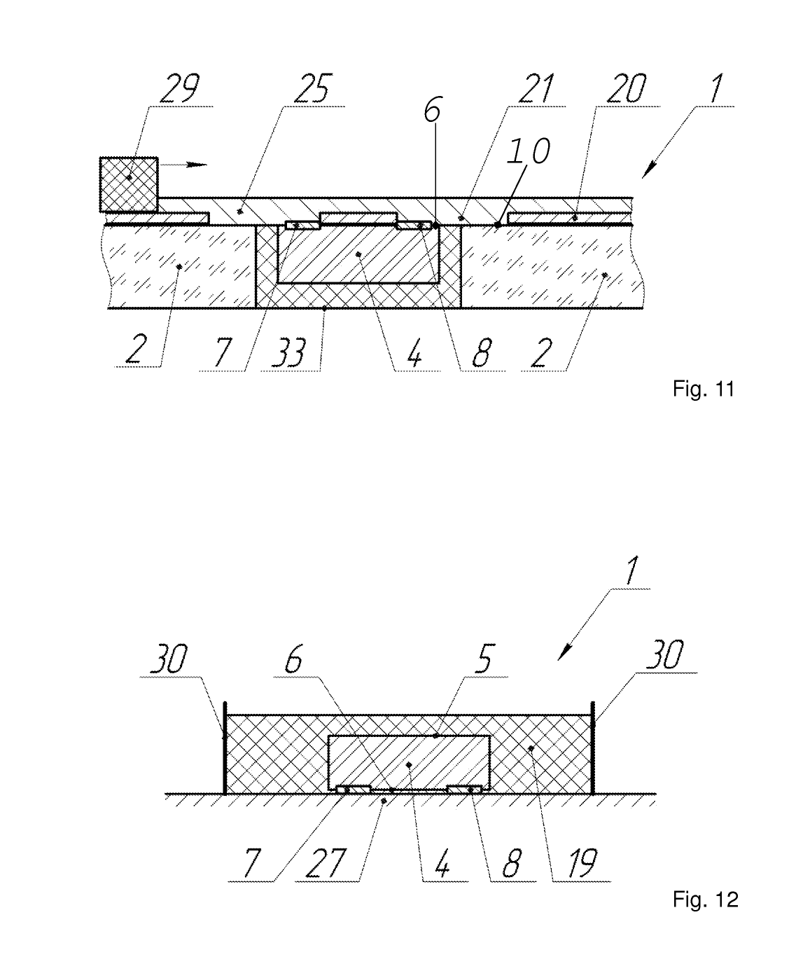

In the case shown in FIG. 2, the light emitted from the LED top surface 5 has to travel through the compound 19 only and exits the compound 19 at a boundary surface 33 of the compound 19, situated at the substrate top side 9. By shaping the boundary surface 33 the compound 19 can be functionalised as optical element. In the embodiment shown in FIG. 2 the boundary surface 33 has a convex shape with respect to the LED top surface 5, realising a convex lens 26 for the light emitted from the LED top surface 5. Other curvatures and shapes of the boundary surface 33 can be employed as well, e.g. a concave shape (not shown) with respect to the LED top surface 5 for realising a concave lens for the light emitted from the LED top surface 5. Of course, it is also possible to waive having a lens 26 and keep a flat boundary surface 33, cf. FIG. 11.

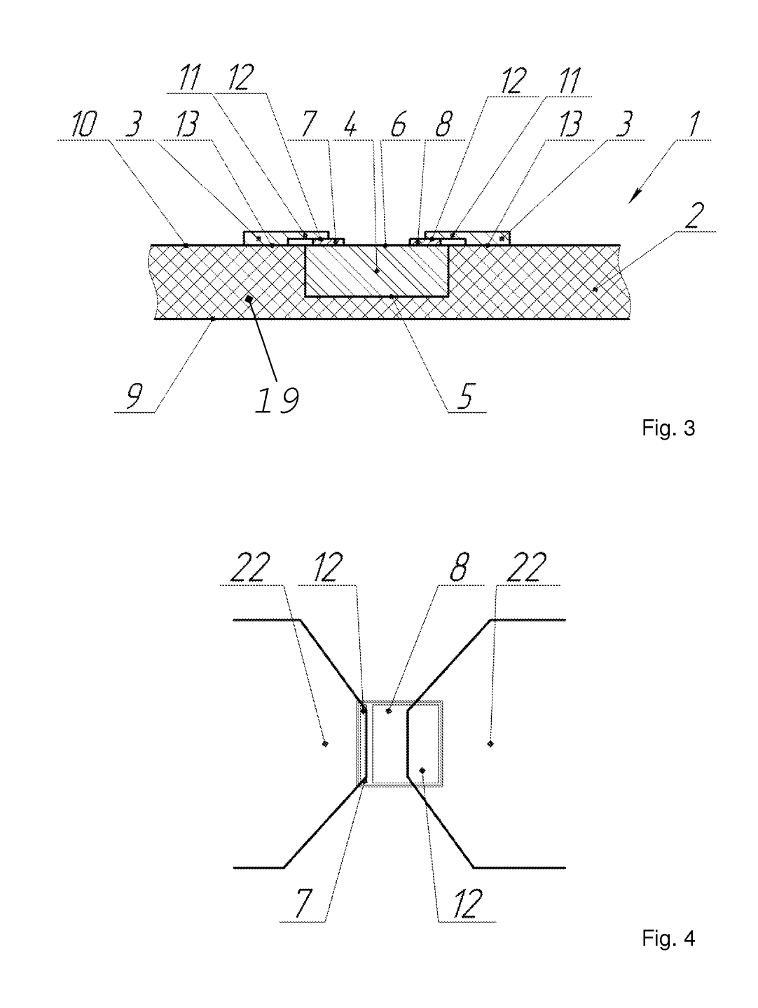

FIG. 3 shows a cut-out of another embodiment where the LED die 4 is embedded—and therefore arranged—in the substrate 2. In the shown example the whole substrate 2 is made of compound 19, fixing the LED die 4 in the substrate 2. Of course, also in this case it is possible to give the substrate top side 9 in the region of the LED top surface 5 a certain shape, in order to realise a boundary surface 33 with a certain curvature and therefore a certain optical element or lens (not shown).

FIG. 12 illustrates how to produce such an LED package 1 with LED dies 4 embedded in the substrate 2. First, the LED dies 4 are fixed on a flat auxiliary support 27 with the LED bottom surface 6 facing the auxiliary support 27. Then, an auxiliary frame 30, which is impermeable for the compound 19, is placed on the auxiliary support 27. Thereby, the auxiliary frame 30 encloses all LED dies 4 of the LED package 1 and delimits the lateral dimensions of the substrate 2. In the next step, compound 19 is filled in between the LED dies 4 such that all LED dies 4 are enclosed by compound 19. In the shown example (FIG. 12) the LED top surface 5 is also covered by compound 19. When enclosing the LED dies 4 with compound 19 it is important to avoid formation of air bubbles. In order to remove air bubbles vacuum degasification may be applied (not shown).

Before the auxiliary frame 30 can be removed and the substrate 2 with the embedded LED dies 4 can be lift off the auxiliary support 27 the compound 19 has to be solidified. Depending on the compound material, solidification can be done in different ways, e.g. by application of heat or by exposure to UV light.

This way of producing an LED package 1 with LED dies 4 embedded in the substrate 2 allows for LED bottom surfaces 6 that are perfectly coplanar with the substrate bottom side 10. The latter facilitates the deposition of a film of conductive material 22 for forming the contact electrodes 11.

Depositing the film of conductive material 22 can be done in different ways. One way is to evaporate metal through openings 21 of a mask 20. The mask 20 needs to be aligned with the contact areas and the anode 7/cathode 8, respectively, of the LED dies 4. The mask 20 openings 21 correspond to the lateral shape of the contact electrodes 11 to be formed. In the example shown in FIG. 6 the mask openings 21 resemble not only a direct image of the contact electrodes 11, but also of circuitry 3. Therefore, when metal is evaporated through the mask openings 21 not only the contact electrodes 11 for all LED dies 4 of the LED package 1, but also circuitry 3 are formed simultaneously, cf. FIG. 7.

The mask 20 typically consists of a stainless steel sheet with a thickness of several tens of microns, e.g. 50 μm. Mask openings 21 can be produced using laser cutting, for example.

By the evaporation process a single layer 23 or multiple layers of metal, like chromium, copper, aluminium, or nickel, can be deposited. In principle, the sequence of layers with different metals can be arbitrarily chosen, including a periodical and an alternating order.

The evaporation of the metal layer/s 23 is preferably done using at least one thermal evaporator and/or at least one magnetron sputtering source and/or at least one electric arc evaporator, with the evaporation being carried out in a vacuum chamber (not shown). The latter typically implies high vacuum conditions with typical pressures of about 10̂-6 mbar or below.

Similarly, the deposition of a film of conductive material 22 can be done by first evaporating metal layer/s 23 and consecutively applying photolithography—including contact and projection photolithography—for forming the contact electrodes 11 and parts of or the whole circuitry 3, respectively. FIG. 8 shows a cut-out of an LED package 1 with LED dies 4 arranged in respective recesses 14 during a step in an exemplary photolithographic process based on contact photolithography. In this case a metal layer 23 or multiple layers of metal (as detailed above) have already been evaporated onto the whole substrate bottom side 10 and the whole LED bottom surface 6. The whole metal layer/s 23 is/are then coated with photoresist 24. The mask 20 with mask openings 21 is then aligned with the anodes 7/cathodes 8 of the LED dies 4. Using UV light, the photoresist 24 is then exposed through the mask openings 21.

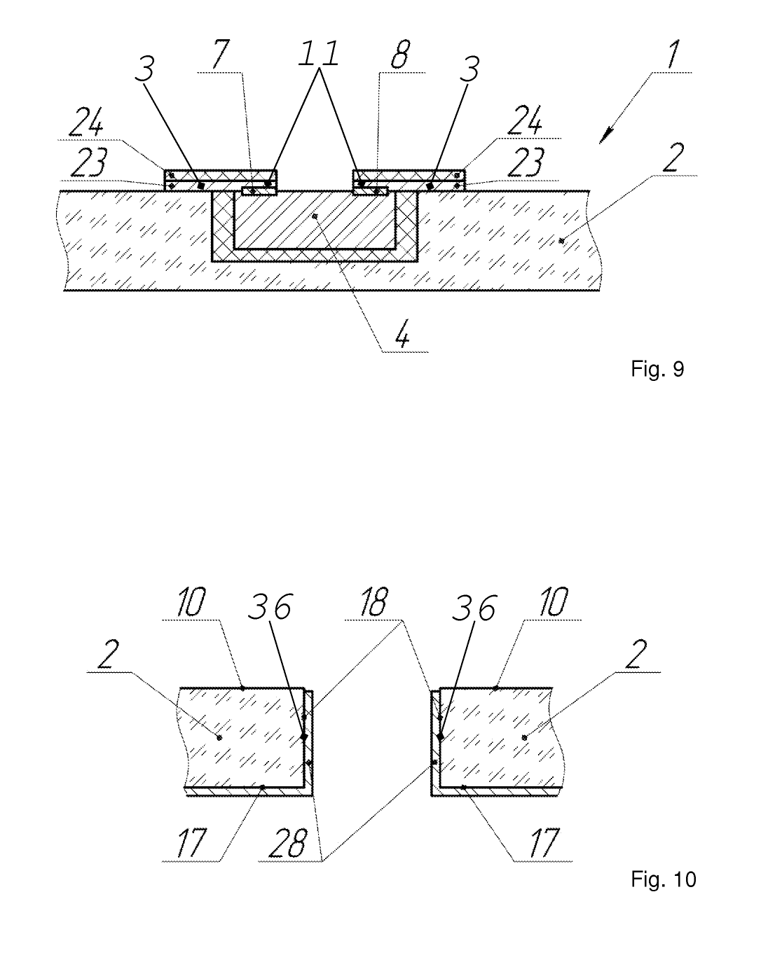

Depending on whether a positive or negative photoresist 24 is used the mask openings 21 resemble a negative or a direct image of the contact electrodes 11—as well as of circuitry 3—to be formed. In the example shown in FIG. 8 a negative photoresist 24 is used, with unexposed regions being soluble by a developer and therefore being washed off in a consecutive developing process. Hence, the mask openings 21 in FIG. 8 resemble a direct image of the contact electrodes 11 and circuitry 3 to be formed. The exposed regions of the photoresist 24 remain in the developing process and protect the underlying metal layer/s 23 from a consecutive etching process. Finally, the contact electrodes 11 and circuitry 3 remain as shown in FIG. 9.

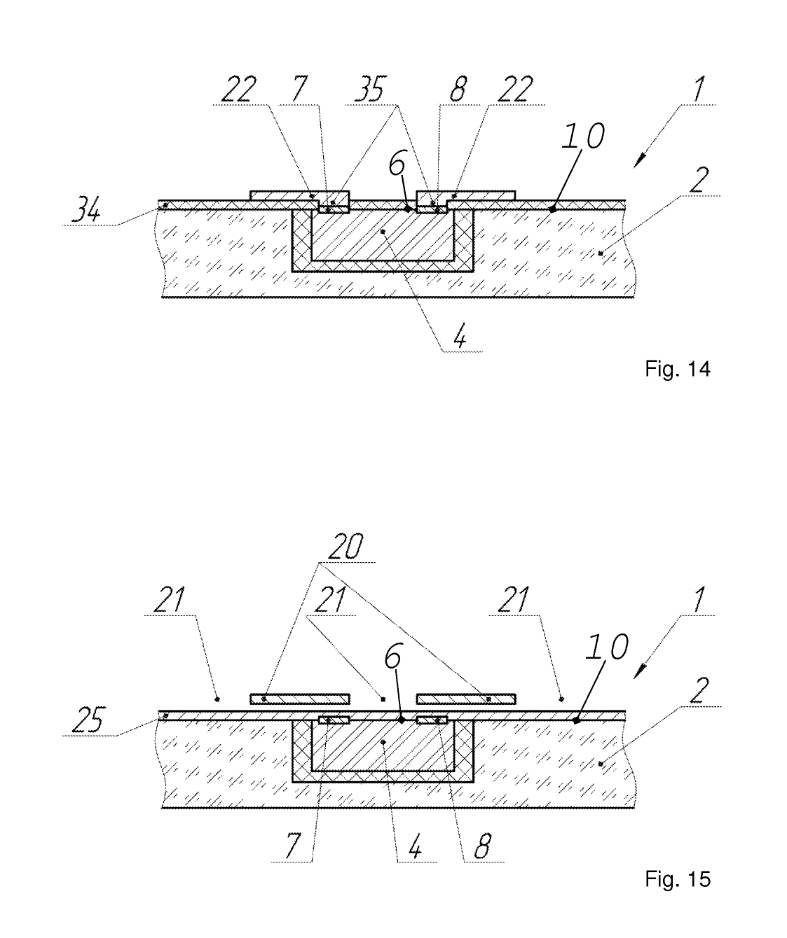

In order to provide for contact electrodes that are essentially coplanar with respect to each other, a dielectric layer 34 can be applied for planarization, c.f. FIG. 14. In this dielectric layer 34, which, for example, is made of a poly(p-xylylene) polymer, also known under the trade name Parylene, openings 35 are formed. These openings 35 resemble a direct image of the planar shape of the contact electrodes 11 to be formed and are correspondingly aligned with the contact areas and anodes 7/cathodes 8, respectively, of the LED dies 4. Metal is evaporated through these dielectric layer openings 35 and onto the dielectric layer 34, thereby forming a continuous film of conductive material 22 and a metal layer 23, respectively, in the dielectric layer openings 35, the dielectric layer 34 and in-between. In a last step the metal layer 23 is removed from the dielectric layer 34 in regions not belonging to the contact electrodes 11 and/or the circuitry 3 and coplanar contact electrodes 11 and/or circuitry 3 remain on the dielectric layer 34, cf. FIG. 14. This last step may be done by photolithography using a mask 20, as described above.

Depositing the film of conductive material 22 may be done also without the necessity of using a vacuum chamber. This is enabled by using a conductive paste 25 as conductive material 22, c.f. FIG. 11. In this case the mask 20—with mask openings 21 resembling a direct image of the contact electrodes 11 and circuitry 3, respectively, to be formed—is aligned with the anodes 7 and cathodes 8 of the LED dies 4 and put onto the substrate bottom side 10 and the LED bottom surface 6, respectively. Then the conductive paste 25 is applied, simply by using a spreading knife 29. In the cut-out of FIG. 11 it is shown how the spreading knife 29 is moved over the mask 20, in order to apply the conductive paste 25 through the mask openings 21 and to remove excess conductive paste 25. The arrow indicates the direction of movement of the spreading knife 29.

After application of the conductive paste 25 the mask 20 is removed and the remaining conductive paste 25 is solidified. Depending on the conductive paste composition, solidification can be done in different ways and typically involves polymerisation of the paste. For example, the conductive paste 25 may be a polymer solution filled with small conductive particles, e.g. with silver powder. In this case polymerisation typically can be triggered by temperature or, for certain types of paste, by solvent evaporation over time.

If a photosensitive conductive paste is used, further steps similar to photolithography are involved, as described above with the help of FIG. 8. Instead of the metal layer/s 23 the photosensitive conductive paste 25 is applied to both the whole substrate bottom side 10 and LED bottom surface 6. A photoresist 24 is not needed in this case. Instead the mask 20 is aligned with the anodes 7 and cathodes 8 of the LED dies 4, directly above the photosensitive conductive paste 25.

Analogously to photolithography, there exist conductive pastes 25 that behave either similar to negative photoresists 24 or similar to positive photoresists 24. This means that depending on the specific type of the conductive paste 25 exposure to UV light can trigger or impede solidification of the conductive paste 25. In the former case, a mask 20 with openings 21 resembling a direct image of the contact electrodes 11 and circuitry 3, respectively, to be formed is used. In the following the “negative” photosensitive conductive paste 25 is exposed to UV light and exposed regions of the photosensitive conductive paste 25 solidify. The mask 20 is then removed and the unexposed photosensitive conductive paste 25 is washed off using a proper solvent, e.g. an alkali solution such as a sodium carbonate (Na₂CO₃) solution.

In case a “positive” conductive paste 25 is employed, a mask 20 with openings 21 resembling a negative image of the contact electrodes 11 and circuitry 3, respectively, to be formed is used, like illustrated in FIG. 15. In the following the “positive” photosensitive conductive paste 25 is exposed to UV light and only the unexposed regions of the photosensitive conductive paste 25 solidify. The mask 20 is then removed and the exposed photosensitive conductive paste 25 is washed off using a proper solvent, e.g. an alkali solution such as a sodium carbonate (Na₂CO₃) solution.

### LIST OF REFERENCE SIGNS

1 LED package
2 Substrate
3 Circuitry
4 LED die
5 LED top surface
6 LED bottom surface
7 Anode
8 Cathode
9 Substrate top side
10 Substrate bottom side
11 Contact electrode
12 Section of a contact area
13 Section of the substrate bottom side
14 Recess in the substrate
15 Hole in the substrate
16 Inner surface of the recess
17 Coated section on the substrate top side
18 Inner surface of the hole
19 Compound
20 Mask
21 Mask opening
22 Conductive material
23 Metal layer
24 Photoresist
25 Conductive paste
26 Lens
27 Auxiliary support
28 Metal coating
29 Spreading knife
30 Auxiliary frame
31 Wire bonding
32 Epoxy case
33 Boundary surface of the compound
34 Dielectric layer
35 Dielectric layer opening
36 Coated section on the inner surface of the hole

1. LED (“light emitting diode”) package (1) comprising a substrate (2) with a top side (9) and a bottom side (10), and at least one LED die (4), the substrate (2) having circuitry (3) arranged on its bottom side (10) for supplying the at least one LED die (4) with power, the at least one LED die (4) comprising a light-emitting top surface (5) and a bottom surface (6) exhibiting at least two separated contact areas (7, 8) for electrical connection, and the bottom surface (6) facing in the same direction as the substrate bottom side (10), characterised in that the at least one LED die (4) is at least partially arranged in the substrate (2), and in that at least one of the at least two contact areas (7, 8) is electrically connected to the circuitry (3) by a contact electrode (11) consisting of a film of conductive material (22).

2. The LED package (1) according to claim 1, characterised in that the film of conductive material (22) forming the respective contact electrode (11) consists of a single layer or of multiple layers of metal, like chromium, copper, aluminium, or nickel.

3. The LED package (1) according to claim 1, characterised in that the film of conductive material (22) forming the respective contact electrode (11) consists of a solidified conductive paste (25).

4. The LED package (1) according to claim 1, characterized in that the bottom surface (6) of the at least one LED die (4) is coplanar with the substrate bottom side (10), with an alignment tolerance of 50 μm or 10 μm.

5. The LED package (1) according to claim 1, characterised in that the at least one LED die (4) is arranged in a respective recess (14) of the substrate (2), comprising an inner surface (16), or in a respective hole (15) of the substrate (2), comprising an inner surface (18).

6. The LED package (1) according to claim 5, characterised in that a section (36) of the inner surface (18) of the respective hole (15) of the substrate (2) is coated with metal (28), for example copper.

7. The LED package (1) according to claim 5, characterised in that the at least one LED die (4) is fixed in the respective recess (14) or in the respective hole (15) by a compound (19), which is positioned between the at least one LED die (4) and the inner surface (16, 18), the compound (19) being a polymer compound like an acrylate, a siloxane, or an epoxy.

8. The LED package (1) according to claim 7, characterised in that the compound (19) has a boundary surface (33) facing into the same direction as the top surface (5) of the LED die (4) and being delimited by the inner surface (18) of the respective hole (15), with the boundary surface (33) having a convex or a concave shape with respect to the top surface (5).

9. The LED package (1) according to claim 7, characterised in that the substrate (2) is made of the same material as a known printed circuit board, for example of aluminium or glass-reinforced epoxy laminate sheets.

10. The LED package (1) according to claim 1, characterised in that the at least one LED die (4) is embedded in the substrate (2), with the substrate (2) being made of a compound (19), the compound (19) being a polymer compound like an acrylate, a siloxane, or an epoxy.

11. A method for producing an LED (“light emitting diode”) package (1) comprising at least one LED die (4) with a light-emitting top surface (5) and a bottom surface (6) exhibiting at least two separated contact areas (7, 8) for electrical connection, characterised in that the method comprises the following steps
arranging of the at least one LED die (4) in a substrate (2), with the bottom surface (6) facing in the same direction as a substrate bottom side (10);
depositing a film of conductive material (22), thereby forming contact electrodes (11) for electrically connecting the at least two contact areas (7, 8) to circuitry (3) on the substrate bottom side (10).

12. The method according to claim 11, characterised in that the contact electrodes (11) are simultaneously formed for two contact areas (7, 8) of each LED die (4).

13. The method according to claim 11, characterised in that the deposition of the film of conductive material (22) comprises the following steps:
aligning a mask (20) with the at least two contact areas (7, 8), the mask (20) having openings (21) corresponding to the shapes of the contact electrodes (11) to be formed;
evaporating a single layer or multiple layers of metal, like chromium, copper, aluminium, or nickel, through the mask openings (21).

14. The method according to claim 11, characterised in that the deposition of the film of conductive material (22) comprises the following steps:
evaporating a single layer (23) or multiple layers of metal, like chromium, copper, aluminium, or nickel, onto the whole bottom surface (6) of the at least one LED die (4) and the substrate bottom side (10);
coating of the metal layer/s (23) with photoresist (24);
aligning a mask (20) with the at least two contact areas (7, 8), the mask (20) having openings (21) corresponding to the shapes of the contact electrodes (11) to be formed;
exposing of the photoresist (24) through the mask openings (21);
removing the mask (20);
developing of the photoresist (24);
etching of sections of the metal layer/s (23) not covered by photoresist (24).

15. The method according to claim 11, characterised in that the deposition of the film of conductive material (22) comprises the following steps:
aligning a mask (20) with the at least two contact areas (7, 8), the mask (20) having openings (21) corresponding to the shapes of the contact electrodes (11) to be formed;
applying of a conductive paste (25) through the mask openings (21);
removing the mask (20);
solidifying of the conductive paste (25).

16. The method according to claim 11, characterised in that the deposition of the film of conductive material (22) comprises the following steps:
applying of a photosensitive conductive paste (25) onto the whole bottom surface (6) of the at least one LED die (4) and the substrate bottom side (10);
aligning a mask (20) with the at least two contact areas (7, 8), the mask (20) having openings (21) corresponding to the shapes of the contact electrodes (11) to be formed;
exposing of the photosensitive conductive paste (25) through the mask openings (21);
removing the mask (20);
removing not-solidified photosensitive conductive paste (25).

17. The method according to claim 11, characterised in that the deposition of the film of conductive material (22) comprises the following steps:
coating of the whole bottom surface (6) of the at least one LED die (4) and the substrate bottom side (10) with an electrically isolating, planar dielectric layer (34);
forming of at least one opening (35) in the dielectric layer (34), with the at least one opening (35) being aligned with the at least two contact areas (7, 8);
evaporating a single layer (23) or multiple layers of metal, like chromium, copper, aluminium, or nickel, onto the dielectric layer (34) and through the at least one opening (35) of the dielectric layer (34);
removing the metal layer/s (23) from regions not belonging to the contact electrodes (11) and/or circuitry (3).

18. The method according to claim 11, characterised in that the arrangement of the at least one LED die (4) in the substrate (2) comprises the following steps:
fixing of the at least one LED die (4) on a flat auxiliary support (27), with the bottom surface (6) facing the auxiliary support (27);
enclosing the at least one LED die (4) with compound (19), wherein the compound (19) is confined within an auxiliary frame (30) fixed on the auxiliary support (27);
solidifying of the compound (19), thereby forming the substrate (2) with at least one embedded LED die (4).

19. The LED package (1) according to claim 3, characterised in that the film of conductive material (22) forming the respective contact electrode (11) consists of a dried conductive ink or a dried solution of conductive polymers.

20. The method according to claim 15, characterized in that applying of a conductive paste (25) through the mask openings (21) is done by using a spreading knife (29).

21. The method according to claim 17, characterised in that the dielectric layer is made of a poly(p-xylylene) polymer or a polyimide.

22. The method according to claim 17, characterised in that forming of at least one opening (35) in the dielectric layer (34) is done using plasma etching, laser ablation, or photolithography.

23. The method according to claim 17, characterised in that removing the metal layer/s (23) from regions not belonging to the contact electrodes (11) and/or circuitry (3) is done using photolithography.
